(19) United States
(12) Patent Application Publication
(10) Pub. No.: US 2024/0421166 A1
(43) Pub. Date: Dec. 19, 2024

(54) SEMICONDUCTOR DEVICE AND METHOD OF MANUFACTURING THE SAME

(71) Applicant: Renesas Electronics Corporation, Tokyo (JP)

(72) Inventors: Makoto KOSHIMIZU, Tokyo (JP); Shigeki TSUBAKI, Tokyo (JP)

(21) Appl. No.: 18/641,596

(22) Filed: Apr. 22, 2024

(30) Foreign Application Priority Data
Jun. 15, 2023 (JP) 2023-098723

(51) Int. Cl. H01L 27/144; H01L 21/762; H01L 23/528; H01L 29/66; H01L 29/78; H01L 31/02

(52) U.S. Cl. CPC H01L 27/1443; H01L 21/76224; H01L 23/5283; H01L 29/66681; H01L 29/7816; H01L 31/02005

(57) ABSTRACT

An anode region and a cathode region of a photodiode are formed in a semiconductor substrate. At a main surface of the semiconductor substrate, a plurality of first STI regions are formed on the cathode region, and an oxide film is formed between the plurality of first STI regions. A shield electrode is formed on the plurality of first STI regions and the oxide film. A thickness of each of the plurality of first STI regions is smaller than a thickness of second STI region.

### CROSS-REFERENCE TO RELATED APPLICATIONS

The disclosure of Japanese Patent Application No. 2023-098723 filed on Jun. 15, 2023, including the specification, drawings and abstract is incorporated herein by reference in its entirety.

### BACKGROUND

The present invention relates to a manufacturing method of a semiconductor device and a semiconductor device, for example, it can be suitably used for a manufacturing method of a semiconductor device including a diode and for a semiconductor device including the diode.

There is a disclosed technique listed below.

[Patent Document 1] Japanese Unexamined Patent Application Publication No. Hei 04-373181

Patent Document 1 discloses a semiconductor device including a photodiode.

### SUMMARY

The semiconductor device including a photodiode includes a semiconductor substrate, an anode region and a cathode region formed in the semiconductor substrate, a dielectric layer formed on the cathode region, and a light-transmitting electrode formed on the dielectric layer. The light-transmitting electrode is formed for noise shielding. The dielectric layer on the cathode region reduces the parasitic capacitance between the light-transmitting electrode and the cathode region. Light that has passed through the light-transmitting electrode and the dielectric: layer underneath enters the cathode region.

The inventor considers using an STI region formed by the STI method as a dielectric layer to electrically isolate the cathode region of the photodiode and the shield electrode. Even in such a case, it is desirable to improve the performance of the semiconductor device.

Other objects and novel features will become apparent from the description of this specification and the accompanying drawings.

According to one embodiment, the manufacturing method of the semiconductor device including a photodiode, the method includes: (a) preparing a semiconductor substrate, (b) forming a plurality of first STI regions at the main surface of the semiconductor substrate, and (c) etching the plurality of first STI regions after the (b). The manufacturing method of the semiconductor device further includes: (d) forming an oxide film between the plurality of first STI regions and at the main surface of the semiconductor substrate by thermal oxidation treatment after the (c), and (e) performing a heat treatment of 1000 degrees Celsius or more on the semiconductor substrate after the (d). The plurality of first STI regions are located in a cathode region of a first conductivity type of the photodiode in plan view.

Also, according to one embodiment, the semiconductor device including a photodiode includes an anode region of a first conductivity type formed in a semiconductor substrate, a cathode region of a second conductivity type formed on the anode region and in the semiconductor substrate, and a first semiconductor region of the first conductivity type formed on the anode region and in the semiconductor substrate. The semiconductor device further includes a plurality of first STI regions formed on the cathode region and at the main surface of the semiconductor substrate, an oxide film formed between the plurality of first STI regions and at the main surface of the semiconductor substrate, and an electrode formed on the plurality of first STI regions and on the oxide film. The semiconductor device further includes a first plug electrically connected to the cathode region, a second plug electrically connected to the first semiconductor region, and a second STI region disposed between the cathode region and the first semiconductor region and at the main surface of the semiconductor substrate. The second plug is electrically connected to the anode region via the first semiconductor region. A thickness of each of the plurality of first STI regions is smaller than a thickness of the second STI region.

According to one embodiment, the performance of the semiconductor device can be improved.

### BRIEF DESCRIPTION OF THE DRAWINGS

FIG. 1 is a main portion cross-sectional view during a manufacturing step of a semiconductor device in one embodiment.

FIG. 2 is a main portion cross-sectional view during the manufacturing step of the semiconductor device following FIG. 1.

FIG. 3 is a main portion cross-sectional view during the manufacturing step of the semiconductor device following FIG. 2.

FIG. 4 is a main portion cross-sectional view during the manufacturing step of the semiconductor device following FIG. 3.

FIG. 5 is a main portion cross-sectional view during the manufacturing step of the semiconductor device following FIG. 4.

FIG. 6 is a main portion cross-sectional view during the manufacturing step of the semiconductor device following FIG. 5.

FIG. 7 is a main portion cross-sectional view during the manufacturing step of the semiconductor device following FIG. 6.

FIG. 8 is a main portion cross-sectional view during the manufacturing step of the semiconductor device following FIG. 7.

FIG. 9 is a main portion cross-sectional view during the manufacturing step of the semiconductor device following FIG. 8.

FIG. 10 is a main portion cross-sectional view during the manufacturing step of the semiconductor device following FIG. 9.

FIG. 11 is a main portion cross-sectional view during the manufacturing step of the semiconductor device following FIG. 10.

FIG. 12 is a main portion cross-sectional view during the manufacturing step of the semiconductor device following FIG. 11.

FIG. 13 is a main portion cross-sectional view during the manufacturing step of the semiconductor device following FIG. 12.

FIG. 14 is a main portion cross-sectional view during the manufacturing step of the semiconductor device following FIG. 13.

FIG. 15 is a main portion cross-sectional view during the manufacturing step of the semiconductor device following FIG. 14.

FIG. 16 is a main portion cross-sectional view during the manufacturing step of the semiconductor device following FIG. 15.

FIG. 17 is a main portion plan view of the semiconductor device in one embodiment.

FIG. 18 is a main portion plan view of the semiconductor device in one embodiment.

FIG. 19 is a main portion cross-sectional view of a semiconductor device in one embodiment.

FIG. 20 is a main portion cross-sectional view of a semiconductor device in a first examined example.

FIG. 21 is a main portion cross-sectional view of a semiconductor device in a second examined example.

FIG. 22 is an explanatory diagram explaining the effects of a step of forming an oxide film by thermal oxidation.

FIG. 23 is an explanatory diagram explaining the effects of a step of forming an oxide film by thermal oxidation.

FIG. 24 is an explanatory diagram explaining the effects of a step of forming an oxide film by thermal oxidation.

### DETAILED DESCRIPTION

In the following embodiments, when required for convenience, the description will be made by dividing into a plurality of sections or embodiments, but except when specifically stated, they are not independent of each other, and one is related to the modified example, detail, supplementary description, or the like of part or all of the other. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle. Furthermore, in the following embodiments, it is needless to say that the constituent elements (including element steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above numerical values and ranges.

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In the drawings used in the embodiments, hatching may be omitted even in the case of cross-sectional view in order to make the drawings easier to see. Also, even in the case of a plan view, hatching may be used to make the drawing easier to see.

Also, a plan view corresponds to a view from a plane substantially parallel to the main surface or the back surface of a semiconductor substrate SUB. Also, the bottom surface and the lower surface have the same meaning. Also, the height position corresponds to the distance away from the back surface of the semiconductor substrate SUB.

### First Embodiment

### Manufacturing Step of Semiconductor Device

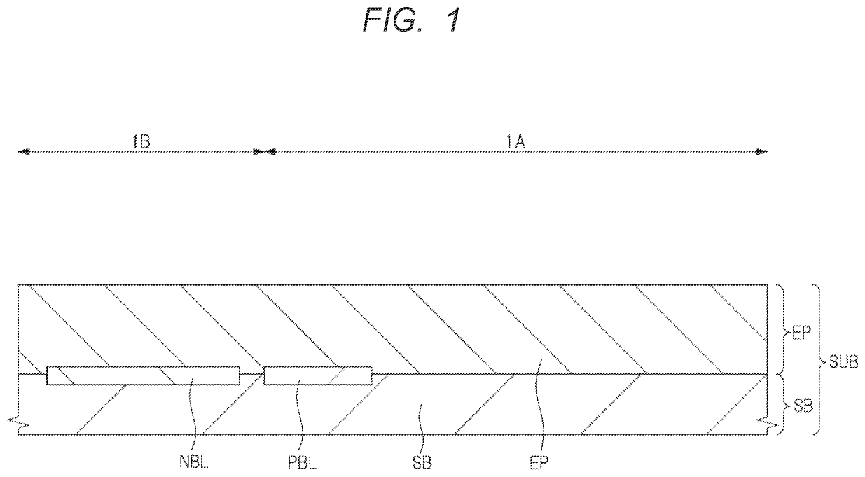

The manufacturing steps of the semiconductor device of the present embodiment is described with reference to the drawings. FIGS. 1 to 16 are cross-sectional views of the main portions during the manufacturing steps of the semiconductor device of the present embodiment.

The semiconductor device of the present embodiment includes a photodiode and a transistor element.

In this application, MOSFET (Metal Oxide Semiconductor Field Effect Transistor) or LDMOSFET includes not only MISFET using an oxide film (silicon oxide film) as a gate dielectric film, but also MISFET using a dielectric film other than an oxide film (silicon oxide film) as a gate dielectric film. The LDMOSFET may also be referred to as HV-MOSFET (High Voltage Metal Oxide Semiconductor Field Effect Transistor) or DEMOSFET (Drain Extended Metal Oxide Semiconductor Field Effect Transistor).

First, as shown in FIG. 1, the semiconductor substrate SUB having a p-type substrate body SB and an n-type semiconductor layer EP is prepared. The p-type substrate body SB is formed of, for example, p-type monocrystalline silicon. The n-type semiconductor layer EP is formed of n-type monocrystalline silicon, which is formed on a main surface of the substrate body SB by epitaxial growth.

The main surface of the semiconductor substrate SUB is synonymous with the main surface of the semiconductor layer EP. Also, the back surface of the semiconductor substrate SUB is synonymous with the back surface of the substrate body SB. The main surface of the semiconductor substrate SUB and the back surface of the semiconductor substrate SUB are located on opposite sides of each other.

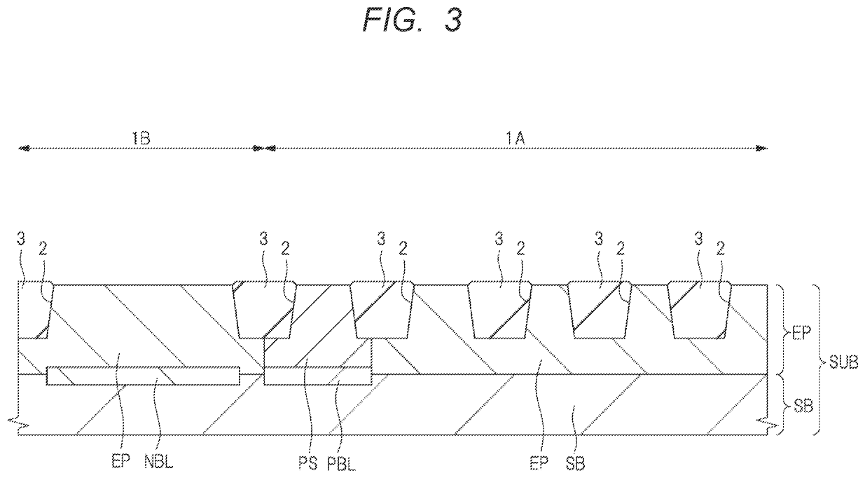

Here, the semiconductor substrate SUB has a photodiode formation region 1A and a transistor formation region 1B. A photodiode is formed in the photodiode formation region 1A. A transistor element is formed in the transistor formation region 1B. The photodiode formation region 1A and the transistor formation region 1B are disposed at different positions on the main surface of the semiconductor substrate SUB. The cross-sectional view of the transistor formation region 1B in FIGS. 3 to 16 shows the cross-sectional view of the active region where the transistor element is formed.

As shown in FIG. 1, in the transistor formation region 1B, an n-type buried layer NBL is formed near the interface between the substrate body SB and the semiconductor layer EP. Also, in a part of the photodiode formation region 1A, a p-type buried layer PBL is formed near the interface between the substrate body SB and the semiconductor layer EP. The n-type buried layer NBL and the p-type buried layer PBL can also be formed before the formation of the semiconductor layer EP. For example, after forming the n-type buried layer NBL and the p-type buried layer PBL in the p-type substrate body SB by ion implantation, the n-type semiconductor layer EP can be formed on the substrate body SB using an epitaxial growth method. The p-type buried layer PBL is formed at a position that does not overlap an n-type well region NW in plan view, which will be formed later.

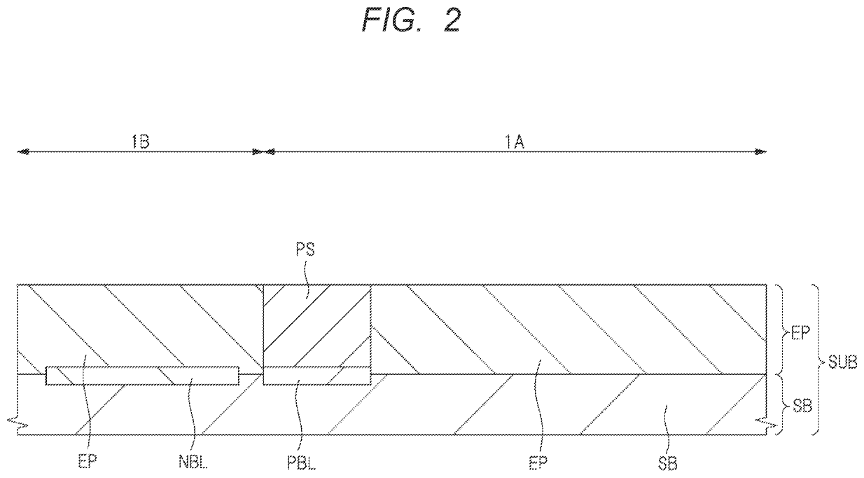

Next, as shown in FIG. 2, a p-type semiconductor region PS is formed in the semiconductor layer EP in the photodiode formation region 1A. The p-type semiconductor region PS is formed to reach the p-type buried layer PBL from n the main surface of the semiconductor substrate SUB.

The p-type semiconductor region PS can be formed by ion-implanting p-type impurities into the semiconductor layer EP and then thermally diffusing the p-type impurities. The p-type semiconductor region PS is formed on the p-type buried layer PBL and in the semiconductor layer EP. Also, the p-type semiconductor region PS is formed at a position that does not overlap the n-type well region NW in plan view, which will be formed later.

Next, as shown in FIG. 3, an STI region (element isolation region) 3 is formed at the main surface of the semiconductor substrate SUB using an STI (Shallow Trench Isolation) method. The STI region 3 is formed of a dielectric film such as a silicon oxide film buried in a trench 2 formed in the semiconductor layer EP. The height position of the bottom surface of the STI region 3 is higher than the height position of the bottom surface of the semiconductor layer EP.

After forming the trench 2 at the main surface of the semiconductor substrate SB, a dielectric film is formed on the main surface of the semiconductor substrate SB to fill the trench 2. Then, the dielectric film outside the trench 2 is removed using a method such as the CMP (Chemical Mechanical Polishing) method. This allows the formation of the STI region 3 formed of the dielectric film buried in the trench 2.

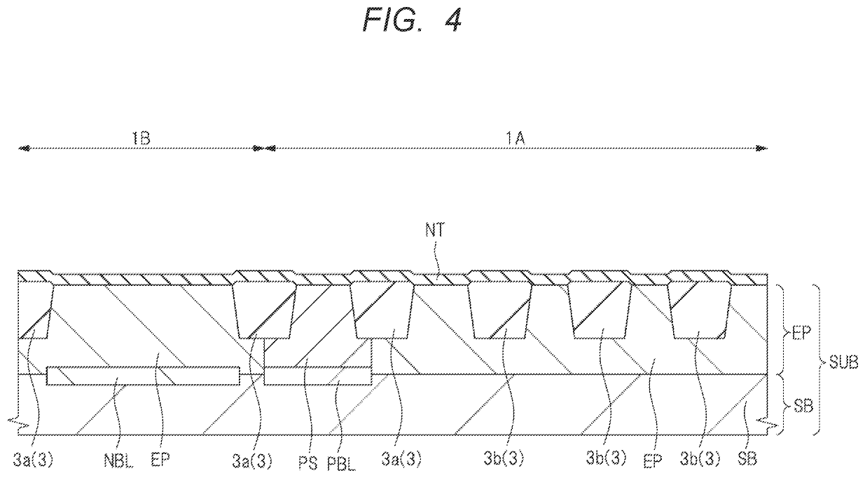

Next, as shown in FIG. 4, a dielectric film NT is formed on the main surface of the semiconductor substrate SUB to cover the STI region 3. The dielectric film NT can be formed by the CVD method (Chemical Vapor Deposition) and is formed of, for example, a silicon nitride film.

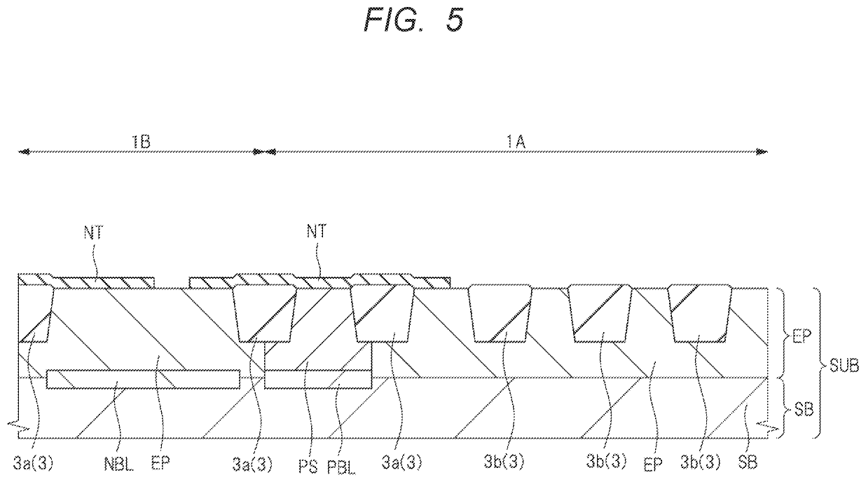

Next, as shown in FIG. 5, after forming a photoresist pattern (not shown) on the dielectric film NT, the dielectric film NT is patterned by using the photoresist pattern as an etching mask and etching the dielectric film NT. In this patterning step, the dielectric film NT is removed in a part of the photodiode formation region 1A and a part of the transistor formation region 1B.

As shown in FIG. 5, in the transistor formation region 1B, a part of the semiconductor layer EP is exposed from the dielectric film NT. Specifically, the dielectric film NT exposes the area where a field oxide film 4 is to be formed. In the transistor formation region 1B, the semiconductor layer EP and the STI region 3, other than the area where the field oxide film 4 is to be formed, are covered with the dielectric film NT.

Also, as shown in FIG. 5, in the photodiode formation region 1A, the p-type semiconductor region PS, the area where an n-type semiconductor region NC is to be formed, and the STI region 3 between the p-type semiconductor region PS and the area where the n-type semiconductor region NC is to be formed are covered with the dielectric film NT. The rest of the semiconductor layer EP and the STI region 3 are exposed from the dielectric film NT. Specifically, in the photodiode formation region 1A, the area where the n-type well region NW is to be formed, excluding the area where the n-type semiconductor region NC is to be formed, is exposed from the dielectric film NT.

The STI region 3 has an STI region 3a and an STI region 3b. The STI region 3a is covered with the dielectric film NT, and the STI region 3b is exposed from the dielectric film NT without being covered. At this stage, the height position of the upper surface of the STI region 3a and the height position of the upper surface of the STI region 3b are the same as each other.

In the transistor formation region 1B, the STI region 3a covered with the dielectric film NT is formed, and the STI region 3b not covered with the dielectric film NT is not formed.

In the photodiode formation region 1A, the STI region 3a covered with the dielectric film NT and the STI region 3b not covered with the dielectric film NT are formed.

Specifically, the STI region 3b is located in the n-type well region NW (and therefore in the n-type cathode region) in plan view when forming the n-type well region NW later. In the photodiode formation region 1A, the STI region 3a is located between a p-type well region PW1 and the n-type well region NW when forming the p-type well region PW1 and the n-type well region NW later. The STI region 3a defines the active region where the transistor element is formed in the transistor formation region 1B.

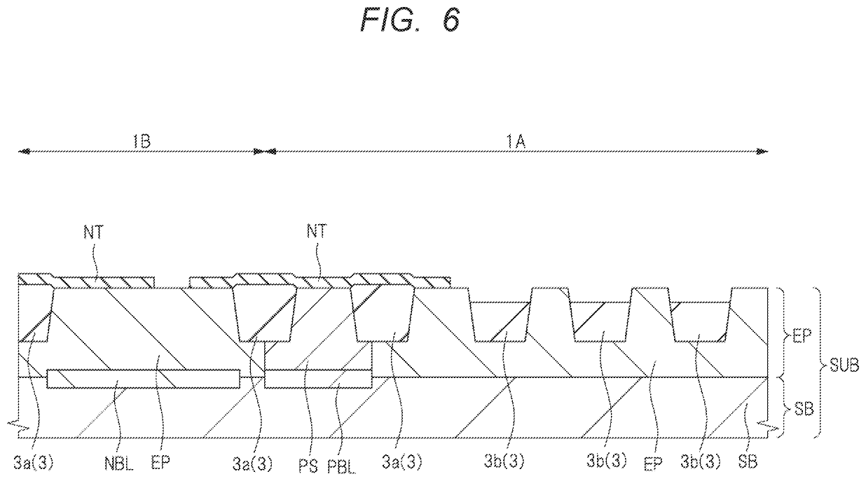

Next, FIG. 6 shows an etching step of etching the STI region 3b.

The etching step of FIG. 6 is performed under etching conditions where the etching rate of the semiconductor layer EP is smaller than the etching rate of the STI region 3b. In the etching step of FIG. 6, the STI region 3b is etched because it is exposed from the photoresist pattern and the dielectric film NT, but the STI region 3a is not etched because it is covered with the photoresist pattern and the dielectric film NT.

However, in the etching step of FIG. 6, not all of the thickness of the STI region 3b is removed by etching, but a part of the thickness of the STI region 3b is removed by etching, and the other part of the thickness of the STI region 3b remains. The etching step of FIG. 6 is performed to reduce the thickness of the STI region 3b. After the etching step of FIG. 6, the STI region 3b remains, but the thickness of the STI region 3b after the etching step of FIG. 6 is smaller than the thickness of the STI region 3b before the etching step of FIG. 6. For example, the difference between the thickness of the STI region 3b after the etching step of FIG. 6 and the thickness of the STI region 3b before the etching step of FIG. 6 is about 50 nm to 200 nm. The thickness of the STI region 3 is the dimension of the STI region 3 in the direction from the main surface to the back surface of the semiconductor substrate SB. In other words, the thickness of the STI region 3 is the distance from the upper surface of the STI region 3 to the bottom surface.

Also, in the etching step of FIG. 6, the STI region 3a is not etched because it is covered with the photoresist pattern and the dielectric film NT. Therefore, the thickness of the STI region 3a does not change before and after the etching step of FIG. 6.

Before the etching step of FIG. 6, the thickness of the STI region 3a and the thickness of the STI region 3b are the same as each other. Also, before the etching step of FIG. 6, the height position of the upper surface of the STI region 3a and the height position of the upper surface of the STI region 3b are the same as each other. After the etching step of FIG. 6, the thickness of the STI region 3b is smaller than the thickness of the STI region 3a. Also, after the etching step of FIG. 6, the height position of the upper surface of the STI region 3b is lower than the height position of the upper surface of the STI region 3a. Also, in both before and after the etching step of FIG. 6, the height position of the bottom surface of the STI region 3a and the height position of the bottom surface of the STI region 3b are the same as each other.

Also, before the etching step of FIG. 6, the height position of the upper surface of the STI region 3b is the same as or higher than the height position of the upper surface of the semiconductor layer EP, but after the etching step of FIG. 6, the height position of the upper surface of the STI region 3b is lower than the height position of the upper surface of the semiconductor layer EP.

After the completion of the etching step of FIG. 6, the photoresist pattern is removed by ashing or the like.

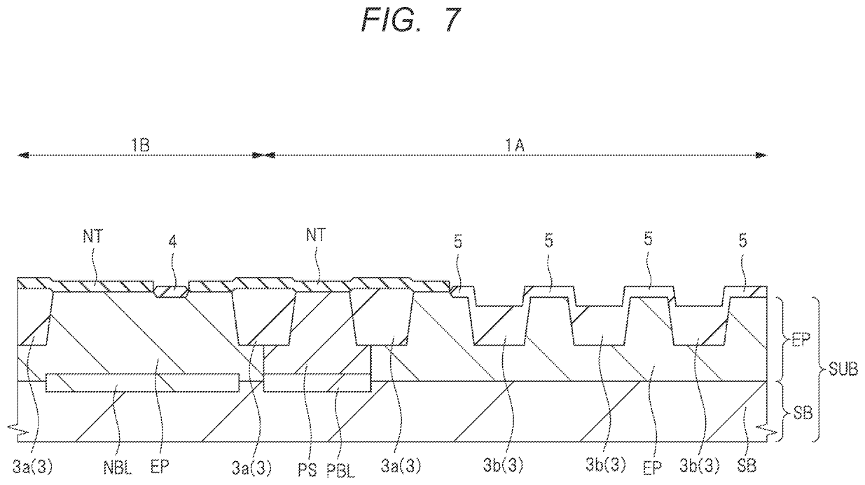

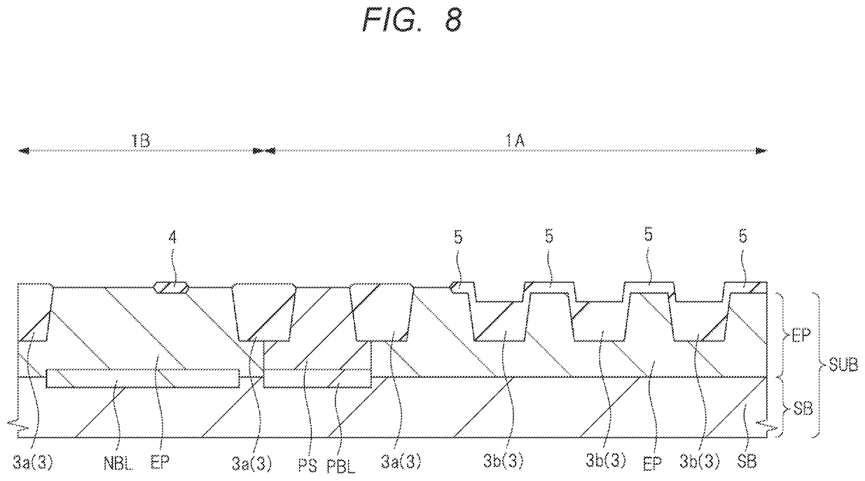

FIG. 7 shows a thermal oxidation step. By performing a thermal oxidation treatment on the semiconductor substrate SUB, the field oxide film 4 and an oxide film 5 are formed as shown in FIG. 7. The heat treatment temperature of the thermal oxidation step in FIG. 7 is, for example, about 950 degrees Celsius to 1100 degrees Celsius. After the thermal oxidation step of FIG. 7, as shown in FIG. 8, the dielectric film NT is removed by etching.

By the thermal oxidation step of FIG. 7, in the transistor formation region 1B, the surface layer (upper part) of the semiconductor layer EP exposed from the dielectric film NT is thermally oxidized, thereby forming the field oxide film 4. The field oxide film 4 is formed by the LOCOS (Local Oxidation of Silicon) method. The field oxide film 4 is, for example, made of a silicon oxide film.

Also, by the thermal oxidation step of FIG. 7, in the photodiode formation region 1A, the surface layer (upper part) of the semiconductor layer EP exposed from the dielectric film NT is thermally oxidized, thereby forming the oxide film 5. The oxide film 5 is, for example, made of a silicon oxide film. The oxide film 5 is formed on the upper surface of the semiconductor layer EP between the adjacent STI regions 3b. The oxide film 5 is not formed on the bottom surface and side surfaces of the trench 2 covered with the STI region 3b, but the oxide film 5 may be formed on a part of the side surfaces of the trench 2 not covered with the STI region 3b. The STI region 3b and the oxide film 5 can be formed integrally. The thickness of the oxide film 5 is smaller than the thickness of the STI region 3b. Also, the thickness of the field oxide film 4 and the thickness of the oxide film 5 are the same.

Also, the p-type semiconductor region PS and the region where the n-type semiconductor region NC is to be formed in the photodiode formation region 1A are covered with the dielectric film NT. Therefore, the oxide film 5 is not formed on the p-type semiconductor region PS and the region where the n-type semiconductor region NC is to be formed.

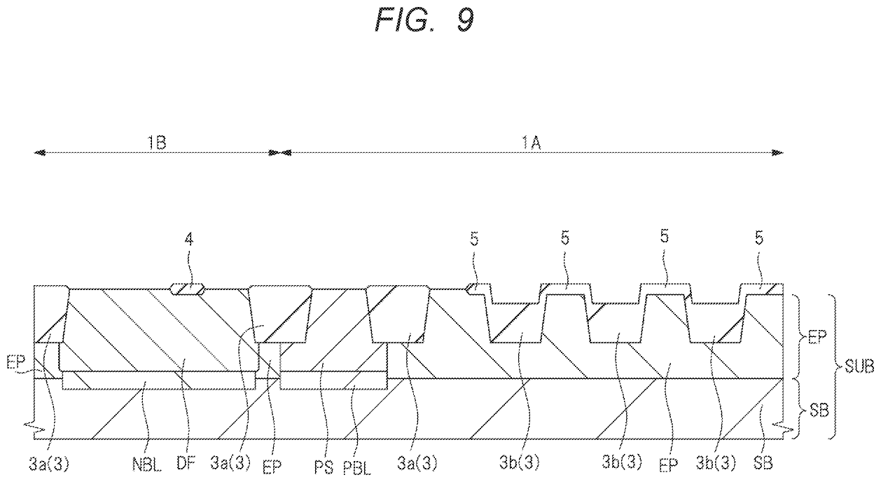

FIG. 9 shows an ion implantation step and a heat treatment step. As shown in FIG. 9, in the transistor formation region 1B, an n-type drift region DF is formed in the semiconductor layer EP by ion implantation and heat treatment. In the transistor formation region 1B, the n-type drift region DF is formed to reach the n-type buried layer NBL from the main surface of the semiconductor layer EP.

A photoresist pattern formed on the semiconductor substrate SUB (not shown) is used as an ion implantation blocking mask, and n-type impurities are implanted into the semiconductor layer EP in the transistor formation region 1B. At the stage immediately after the ion implantation step of FIG. 9, the bottom surface of the n-type drift region DF does not reach the n-type buried layer NBL, and the bottom surface of the n-type drift region DF is separated from the n-type buried layer NBL. After the ion implantation step of FIG. 9, the photoresist pattern is removed, and then a heat treatment is performed to diffuse the n-type impurities. By the heat treatment step of FIG. 9, the n-type impurities implanted by the ion implantation step of FIG. 9 diffuse in the direction from the main surface to the back surface of the semiconductor substrate SUB. As a result, as shown in FIG. 9, the bottom surface of the n-type drift region DF reaches the n-type buried layer NBL. As a result, the n-type drift region DF is formed from the main surface of the semiconductor layer EP to the n-type buried layer NBL. That is, the n-type drift region DF is formed on the n-type buried layer NBL so as to contact the n-type buried layer NBL. By forming the n-type drift region DF by ion implantation and subsequent heat treatment, the n-type drift region DF can be formed to a deep position of the semiconductor substrate SUB.

The heat treatment temperature in the heat treatment step of FIG. 9 is 1000 degrees Celsius or more, preferably about 1100 degrees Celsius to 1200 degrees Celsius.

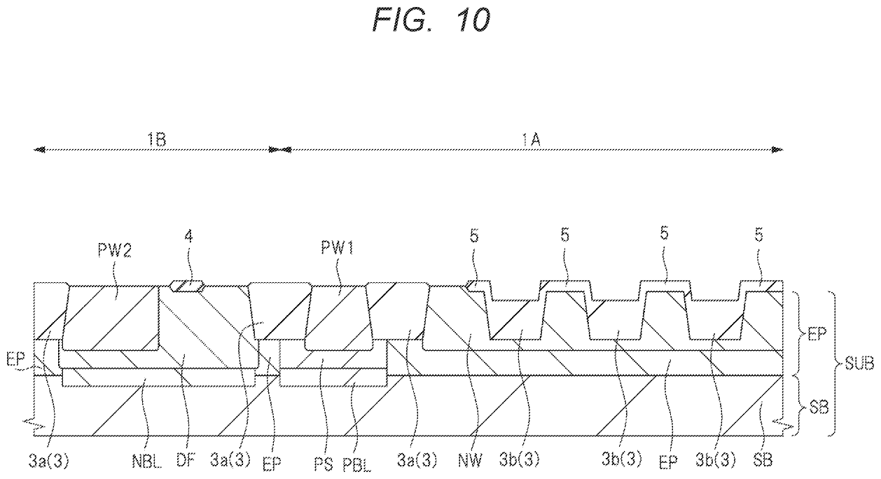

Next, as shown in FIG. 10, the n-type well region NW is formed using an ion implantation method. The n-type well region NW is an n-type semiconductor region.

The n-type well region NW is formed in the semiconductor layer EP in the photodiode formation region 1A. The n-type impurity concentration of the n-type well region NW is higher than the n-type impurity concentration of the n-type semiconductor layer EP. The height position of the bottom surface of the n-type well region NW is higher than the height position of the bottom surface of the semiconductor layer EP. Therefore, the n-type semiconductor layer EP exists under the n-type well region NW, and the p-type substrate body SB exists under the n-type semiconductor layer EP.

Also, the height position of the bottom surface of the n-type well region NW is lower than the height position of the bottom surface of the STI region 3b. The n-type well region NW is continuously formed under the STI region 3b and under the oxide film 5. That is, the n-type well region NW covers the bottom surface of the STI region 3b and the bottom surface of the oxide film 5. Also, the n-type well region NW is formed under the region where the n-type semiconductor region NC is to be formed and under the region.

The n-type well region NW can be formed by using a photoresist pattern (not shown) as an ion implantation mask and ion-implanting n-type impurities into a part of the semiconductor layer EP in the photodiode formation region 1A. At this time, the n-type well region NW is formed by the n-type impurity ions that have passed through the STI region 3b and the oxide film 5.

Next, as shown in FIG. 10, the p-type well region PW1 and a p-type well region PW2 are formed using an ion implantation method. The p-type well region PW1 and the p-type well region PW2 are each a p-type semiconductor region. In plan view, the n-type well region NW and the p-type well region PW1 and the p-type well region PW2 do not overlap each other and are separated from each other.

The p-type well region PW1 is formed in the semiconductor layer EP in the photodiode formation region 1A, and more specifically, is formed in the upper part of the p-type semiconductor region PS. That is, in plan view, the p-type well region PW1 is included in the p-type semiconductor region PS. The height position of the bottom surface of the p-type well region PW1 is higher than the height position of the bottom surface of the p-type semiconductor region PS. The bottom surface of the p-type well region PW1 is in contact with the p-type semiconductor region PS. The p-type impurity concentration of the p-type well region PW1 is higher than the p-type impurity concentration of the p-type semiconductor region PS.

In plan view, the n-type well region NW does not overlap any of the p-type buried layer PBL, the p-type semiconductor region PS, and the p-type well region PW1. Therefore, the bottom surface of the n-type well region NW is in contact with the n-type semiconductor layer EP.

The p-type well region PW2 is formed in the semiconductor layer EP in the transistor formation region 1B, and more specifically, is formed in the n-type drift region DF. In plan view, the p-type well region PW2 is included in the n-type drift region DF. The height position of the bottom surface of the p-type well region PW2 is higher than the height position of the bottom surface of the n-type drift region DF.

The p-type well region PW1 and the p-type well region PW2 can be formed by using a photoresist pattern (not shown) as an ion implantation mask and ion-implanting p-type impurities into a part of the semiconductor layer EP in the photodiode formation region 1A and a part of the semiconductor layer EP in the transistor formation region 1B. It is preferable to form the p-type well region PW1 and the p-type well region PW2 by the same ion implantation step, but they can also be formed by separate ion implantation steps.

In the present embodiment, the p-type well region PW1 and the p-type well region PW2 are formed after forming the n-type well region NW, but the n-type well region NW can also be formed after forming the p-type well region PW1 and the p-type well region PW2.

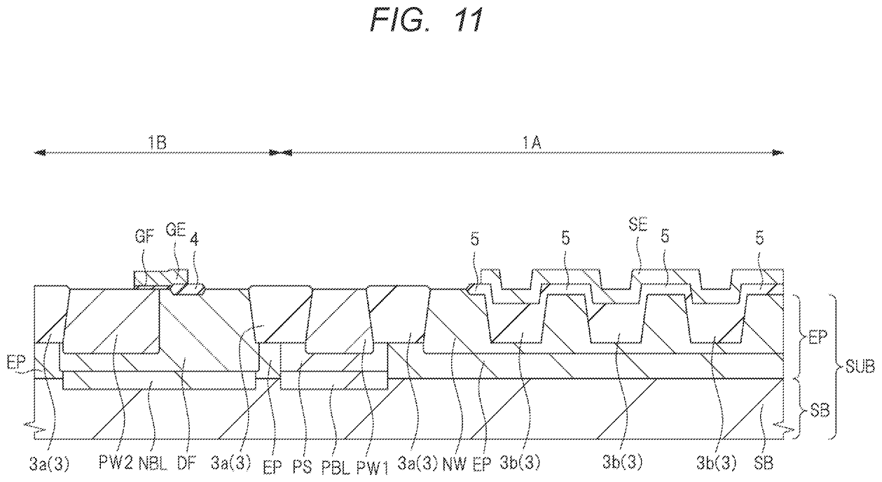

Next, as shown in FIG. 11, a gate dielectric film GF, a gate electrode GE, and a shield electrode SE are formed. The shield electrode SE and the gate electrode GE are made of a polycrystalline silicon film. The shield electrode SE and the gate electrode GE are not connected and are separated from each other. The gate dielectric film GF is formed of, for example, a silicon oxide film.

A dielectric film is formed on the exposed surface of the semiconductor layer EP. Then, a polysilicon film is formed on the dielectric film, on the STI region 3a and the STI region 3b, on the field oxide film 4, and on the oxide film 5. Subsequently, by patterning the polysilicon film using photolithography and etching techniques, the shield electrode SE and the gate electrode GE made of the polysilicon film can be formed. Also, by patterning the dielectric film using photolithography and etching techniques, the dielectric film other than the one located under the gate electrode GE are removed, and the gate dielectric film GF made of the remaining dielectric film under the gate electrode GE is formed.

In the photodiode formation region 1A, the shield electrode SE is continuously formed over the STI region 3b and the oxide film 5. In the transistor formation region 1B, the gate electrode GE is formed on the semiconductor layer EP via the gate dielectric film GF, and a part of the gate electrode GE is located on the field oxide film 4.

Next, after forming a low impurity concentration n-type semiconductor region (not shown) for the LDD (Lightly doped Drain) structure in the p-type well region PW2 in the transistor formation region 1B using ion implantation, sidewall dielectric films (not shown) are formed on the sidewalls of the gate dielectric film GF and the shield electrode SE, respectively.

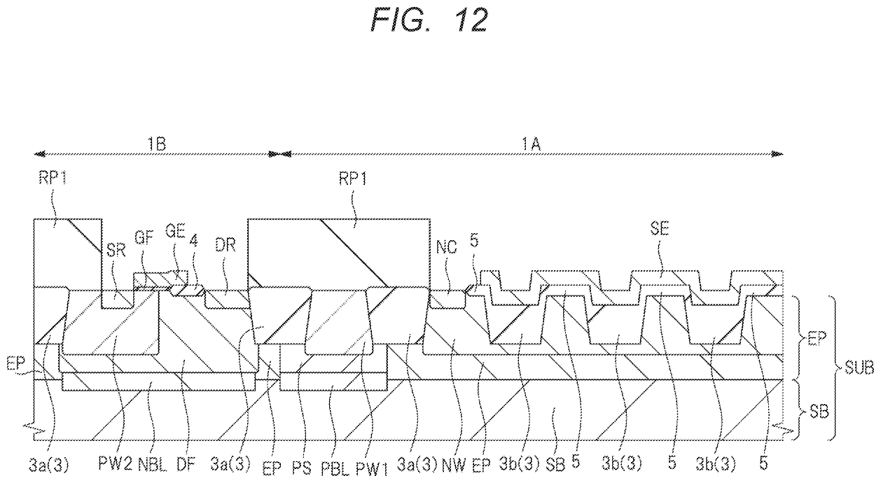

Next, as shown in FIG. 12, the n-type semiconductor region NC, an n-type source region SR, and an n-type drain region DR are formed using ion implantation. The n-type source region SR functions as a source region of the LDMOSFET. The n-type drain region DR functions as a drain region of the LDMOSFET.

For example, after forming a photoresist pattern RP1 as shown in FIG. 12, the n-type semiconductor region NC, the n-type source region SR, and the n-type drain region DR can be formed by using the photoresist pattern RP1 as an ion implantation blocking mask and implanting n-type impurities into the semiconductor substrate SUB. Subsequently, the photoresist pattern RP1 is removed by ashing or the like. The n-type semiconductor region NC, the n-type source region SR, and the n-type drain region DR are preferably formed by the same ion implantation step, but can also be formed by separate ion implantation steps.

The n-type semiconductor region NC is formed in the semiconductor layer EP in the photodiode formation region 1A, more specifically, in the upper part of the n-type well region NW. In plan view, the n-type semiconductor region NC is included in the n-type well region NW. The height position of the bottom surface of the n-type semiconductor region NC is higher than the height position of the bottom surface of the n-type well region NW. The bottom surface of the n-type semiconductor region NC is in contact with the n-type well region NW. The n-type impurity concentration of the n-type semiconductor region NC is higher than the n-type impurity concentration of the n-type well region NW.

In plan view, the n-type semiconductor region NC hardly overlaps the oxide film 5 and the STI region 3b. In other words, most of the n-type semiconductor region NC is not covered with the oxide film 5 and the STI region 3b. The n-type semiconductor region NC is formed in the n-type well region NW exposed from the STI region 3b and the oxide film 5.

The n-type drain region DR is formed in the semiconductor layer EP in the transistor formation region 1B, more specifically, in the n-type drift region DF. In plan view, the n-type drain region DR is included in the n-type drift region DF. The height position of the bottom surface of the n-type drain region DR is higher than the height position of the bottom surface of the n-type drift region DF. The bottom surface of the n-type drain region DR is in contact with the n-type drift region DF. The n-type impurity concentration of the n-type drain region DR is higher than the n-type impurity concentration of the n-type drift region DF.

The n-type source region SR is formed in the semiconductor layer EP in the transistor formation region 1B, more specifically, in the p-type well region PW2. In plan view, the n-type source region SR is included in the p-type well region PW2. The height position of the bottom surface of the n-type source region SR is higher than the height position of the bottom surface of the p-type well region PW2. The bottom surface of the n-type source region SR is in contact with the p-type well region PW2.

In the ion implantation step for forming the n-type semiconductor region NC, the n-type source region SR and the n-type drain region DR, the field oxide film 4 and the gate electrode GE can also function as an ion implantation blocking mask. Therefore, the n-type drain region DR is self-aligned and formed near one end of the field oxide film 4. Also, the n-type source region SR is self-aligned and formed near the drain side sidewall of the gate electrode GE or near the sidewall dielectric film (not shown) on the sidewall. Therefore, in plan view, the gate electrode GE is disposed between the n-type source region SR and the n-type drain region DR. Also, in plan view, the field oxide film 4 is disposed adjacent to the drain region DR between the n-type drain region DR and the source region SR. The n-type source region SR may also have an LDD structure.

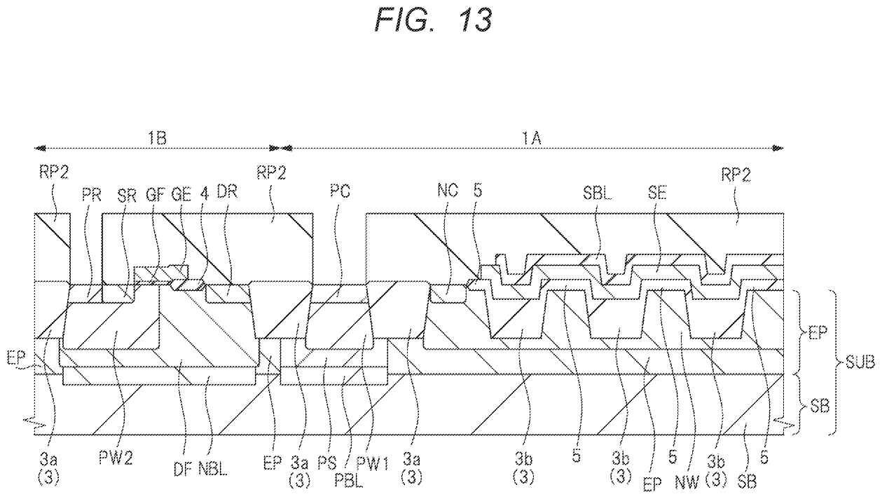

Next, as shown in FIG. 13, a p-type semiconductor region PC and a p-type semiconductor region PR are formed using an ion implantation method.

For example, after forming the photoresist pattern RP2 as shown in FIG. 13, the p-type semiconductor region PC and the p-type semiconductor region PR can be formed by using the photoresist pattern RP2 as an ion implantation blocking mask and implanting p-type impurities into the semiconductor substrate SUB. Subsequently, the photoresist pattern RP2 is removed by ashing or the like. The p-type semiconductor region PC and the p-type semiconductor region PR are preferably formed by the same ion implantation step, but can also be formed by separate ion implantation steps.

The p-type semiconductor region PC is formed in the semiconductor layer EP in the photodiode formation region 1A, more specifically, in the p-type well region PW1. That is, in plan view, the p-type semiconductor region PC is included in the p-type well region PW1. The height position of the bottom surface of the p-type semiconductor region PC is higher than the height position of the bottom surface of the p-type well region PW1. The bottom surface of the p-type semiconductor region PC is in contact with the p-type well region PW1. The p-type impurity concentration of the p-type semiconductor region PC is higher than the p-type impurity concentration of the p-type well region PW1.

The p-type well region PW1 exists under the p-type semiconductor region PC, the p-type semiconductor region PS exists under the p-type well region PW1, the p-type buried layer PBL exists under the p-type semiconductor region PS, the p-type substrate body SB exists under the p-type buried layer PBL. Therefore, the p-type semiconductor region PC, the p-type well region PW1, the p-type semiconductor region PS, the p-type buried layer PBL, and the p-type substrate body SB are electrically connected to each other.

The p-type semiconductor region PR is formed in the semiconductor layer EP in the transistor formation region 1B, more specifically, in the p-type well region PW2. In plan view, the p-type semiconductor region PR is included in the p-type well region PW2. The height position of the bottom surface of the p-type semiconductor region PR is higher than the height position of the bottom surface of the p-type well region PW2. The bottom surface of the p-type semiconductor region PR is in contact with the p-type well region PW2. The p-type impurity concentration of the p-type semiconductor region PR is higher than the p-type impurity concentration of the p-type well region PW2.

The p-type semiconductor region PR and the n-type source region SR are adjacent to each other in the gate length direction of the gate electrode GE. In plan view, the n-type source region SR is located between the p-type semiconductor region PR and the gate electrode GE.

In the present embodiment, the n-type semiconductor region NC, the n-type region SR, semiconductor and the n-type semiconductor region DR are formed after forming the p-type semiconductor region PC and the p-type semiconductor region PR, but the p-type semiconductor region PC and the p-type semiconductor region PR can also be formed after forming the n-type semiconductor region NC, the n-type semiconductor region SR, and the n-type semiconductor region DR.

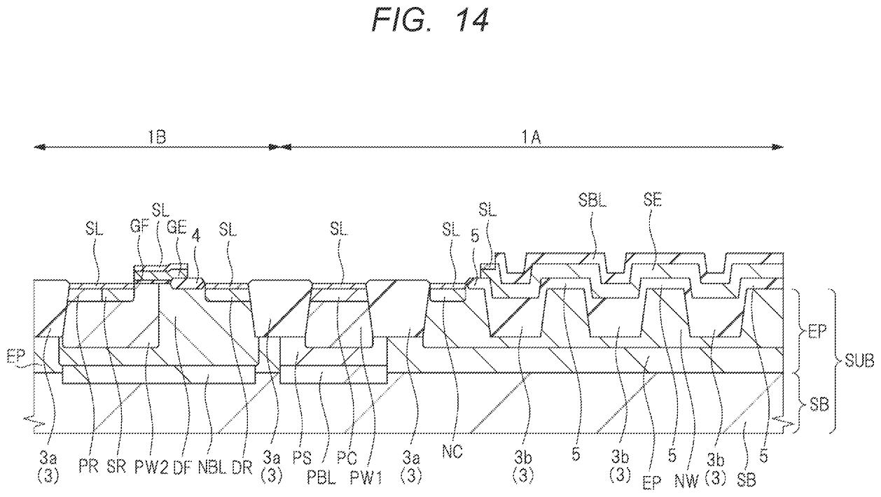

Next, as shown in FIG. 14, a dielectric film SBL is formed on the shield electrode SE. The dielectric film SBL can be formed by forming a dielectric film on the semiconductor substrate SUB, and then patterning the dielectric film by photolithography and etching techniques. The dielectric film SBL exposes a part of the upper surface of the shield electrode SE and covers the other part of the upper surface of the shield electrode SE.

Next, as shown in FIG. 14, a metal silicide layer SL is formed. The metal silicide layer SL can be formed using a salicide (Self Aligned Silicide) technique. The metal silicide layer SL is formed of cobalt silicide, nickel silicide, or platinum-added nickel silicide.

The metal silicide layer SL can be formed on the upper part of each of the gate electrode GE, the p-type semiconductor region PC, the n-type semiconductor region NC, the n-type drain region DR, the n-type source region SR, and the p-type semiconductor region PR. Also, the metal silicide layer SL is formed on a part of the shield electrode SE. Specifically, the metal silicide layer SL is formed on the upper surface of the shield electrode SE exposed from the dielectric film SBL. The metal silicide layer SL is not formed on the upper surface of the shield electrode SE covered with the dielectric film SBL.

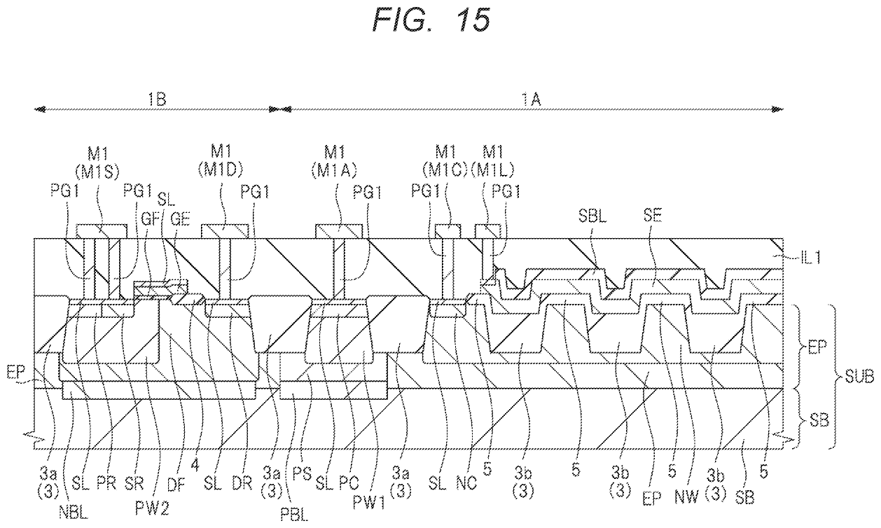

Next, as shown in FIG. 15, a dielectric film IL1 is formed on the main surface of the semiconductor substrate SUB to cover the gate electrode GE, the shield electrode SE, and the dielectric film SBL, using a CVD method or the like. The dielectric film IL1 is formed of, for example, a laminated film of a silicon nitride film and a silicon oxide film thereon. After forming the dielectric film IL1, the upper surface of the dielectric film IL1 can be polished and flattened using a CMP method or the like.

Next, as shown in FIG. 15, by etching the dielectric film IL1 using a photoresist pattern (not shown) formed on the dielectric film IL1 as an etching mask, a contact hole (through hole) is formed in the dielectric film IL1. Subsequently, a conductive plug PG1 is formed in the contact hole.

For example, a barrier conductor film is formed on the dielectric film IL1, which includes the bottom surface and sidewalls of the contact hole. A main conductor film, made of tungsten or the like, is formed on the barrier conductor film so as to fill the contact hole. Subsequently, the main conductor film and the barrier conductor film outside the contact hole are removed by a CMP method or the like. This allows for the formation of the plug PG1.

Next, as shown in FIG. 15, a wiring M1 is formed on the dielectric film IL1. For example, a conductive film is formed on the dielectric film IL1. Subsequently, by patterning the conductive film using photolithography and etching techniques, the wiring M1 made of the conductive film can be formed. The wiring M1 is preferably an aluminum wiring, but other metal wiring, such as tungsten wiring, can also be applied. In addition, copper wiring formed using damascene techniques can also be applied as the wiring M1.

The wiring M1 includes a source wiring M1S, a drain wiring M1D, a cathode wiring M1C, an anode wiring M1A, and a wiring M1L. The source wiring M1S is electrically connected to the n-type source region SR via the metal silicide layer SL and the plug PG1 disposed on the n-type source region SR. The drain wiring M1D is electrically connected to the n-type drain region DR via the metal silicide layer SL and the plug PG1 disposed on the n-type drain region DR. The cathode wiring M1C is electrically connected to the n-type semiconductor region NC via the metal silicide layer SL and the plug PG1 disposed on the n-type semiconductor region NC. The anode wiring M1A is electrically connected to the p-type semiconductor region PC via the metal silicide layer SL and the plug PG1 disposed on the p-type semiconductor region PC. The wiring M1L is electrically connected to the shield electrode SE via the metal silicide layer SL and the plug PG1 disposed on the shield electrode SE. The source wiring M1S, the drain wiring M1D, the cathode wiring M1C, the anode wiring M1A, and the wiring M1L are not connected and are separated from each other.

The source wiring M1S is electrically connected to the p-type semiconductor region PR via the metal silicide layer SL and the plug PG1 disposed on the p-type semiconductor region PR. Therefore, the source potential supplied from the source wiring M1S to the n-type source region SR via the plug PG1 is supplied from the source wiring M1S to the p-type semiconductor region PR via the plug PG1, and further supplied from the p-type semiconductor region PR to the p-type well region PW2.

In addition, the wiring Ml can further include a gate wiring that electrically connects to the gate electrode GE via the plug PG1, but the gate wiring is not shown in FIG. 15.

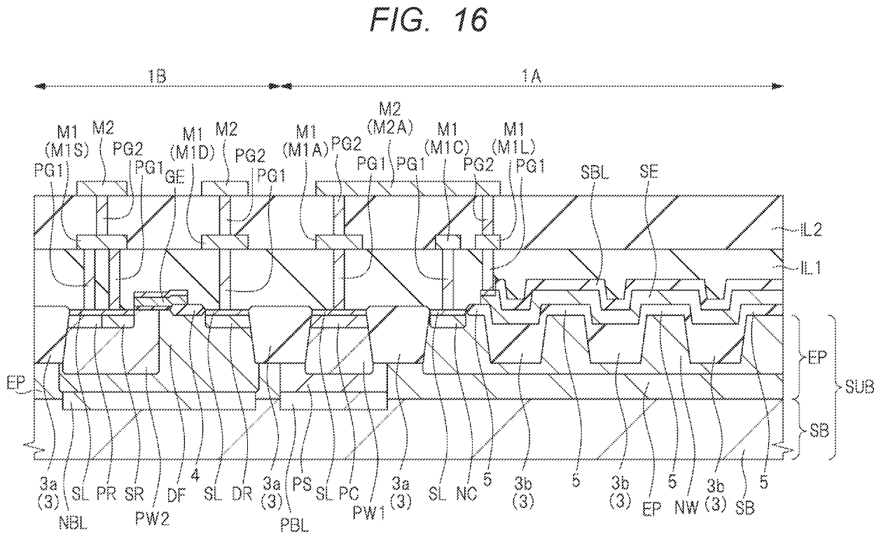

Next, as shown in FIG. 16, a dielectric film IL2 is formed on the dielectric film IL1 so as to cover the wiring M1. Subsequently, a contact hole is formed in the dielectric film IL2, and a conductive plug PG2 is formed in the contact hole. Subsequently, as shown in FIG. 16, a wiring M2 is formed on the dielectric film IL2.

The wiring M2 includes a wiring M2A that electrically connects the anode wiring M1A and the wiring M1L. The wiring M2A is electrically connected to the anode wiring M1A via the plug PG2 disposed on the anode wiring M1A, and is also electrically connected to the wiring M1L via the plug PG2 disposed on the wiring M1L. The shield electrode SE is electrically connected to the p-type semiconductor region PC via the wiring M1L, the wiring M2A, the anode wiring M1A, the plugs PG1, PG2, and the metal silicide layer SL. Therefore, the potential of the shield electrode SE becomes the same as the potential of the p-type semiconductor region PC.

It is possible to form further upper dielectric films and wiring, but their illustration and explanation are omitted.

### Structure of Semiconductor Device

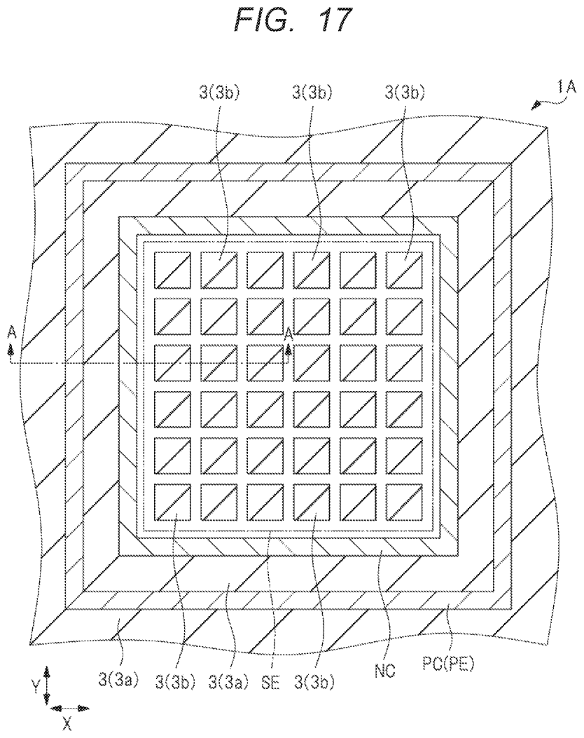

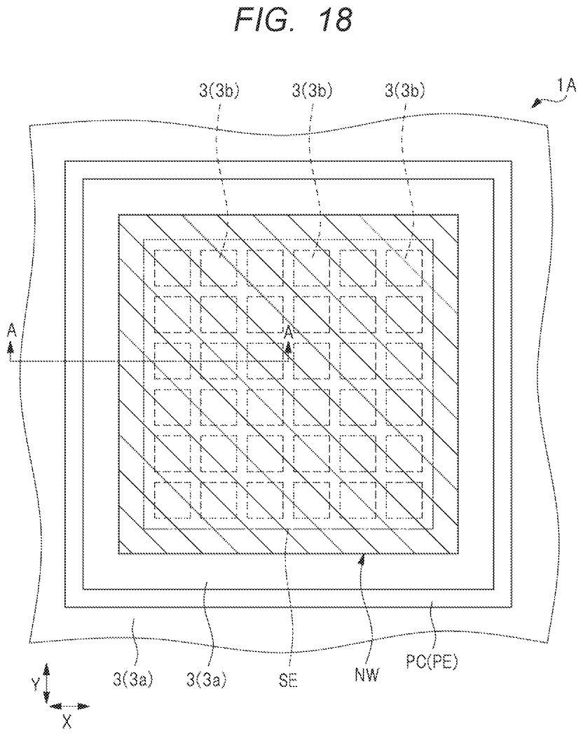

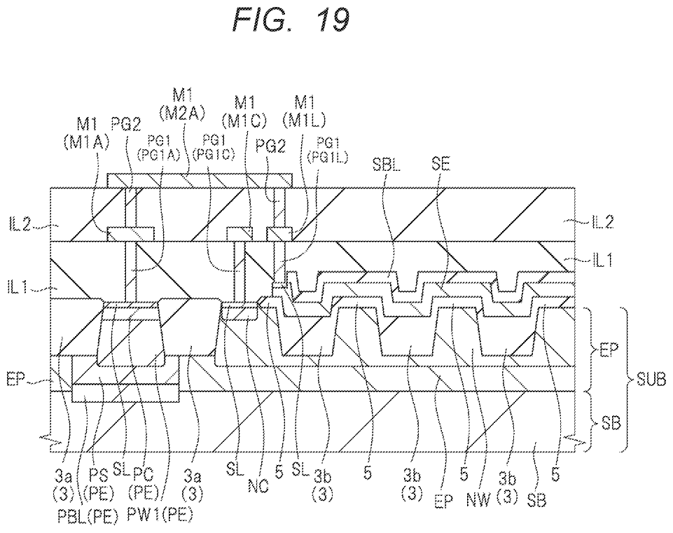

FIGS. 17 and 18 are main portion plan views of the semiconductor device of the present embodiment, and FIG. 19 is a main portion cross-sectional view of the semiconductor device of the present embodiment. FIGS. 17 and 18 show a plan view of the photodiode formation region 1A described above. FIG. 19 corresponds to the cross-sectional view along line A-A shown in FIGS. 17 and 18. Also, the cross-section of the photodiode formation region 1A in FIGS. 1 to 16 corresponds to the cross-sectional view along line A-A shown in FIGS. 17 and 18. FIG. 17 is a plan view, but for ease of understanding, hatching is applied to the STI region 3, the n-type semiconductor region NC, and the p-type semiconductor region PC. Also, FIG. 18 is a plan view, but for ease of understanding, hatching is applied to the n-type well region NW.

The semiconductor device of the present embodiment includes the semiconductor substrate SUB having the p-type substrate body SB and the n-type semiconductor layer EP thereon, the n-type well region NW, the n-type semiconductor region NC, the p-type semiconductor region PS, the p-type well region PW1 and the p-type semiconductor region PC formed in the semiconductor layer EP, and the STI region 3 and the oxide film 5 formed at the main surface of the semiconductor substrate SUB.

The n-type well region NW is located near the center of the photodiode formation region 1A and, as shown in FIG. 18, has a rectangular planar shape. The bottom surface of the n-type well region NW is covered with the n-type semiconductor layer EP. The n-type semiconductor layer EP exists under the n-type well region NW, and the p-type substrate body SB exists under the n-type semiconductor layer EP. The n-type well region NW and the n-type semiconductor layer EP under the n-type well region NW function as the n-type cathode region of the photodiode. And, the p-type substrate body SB functions as the p-type anode region of the photodiode. The photodiode is formed by the n-type cathode region and the p-type anode region being adjacent to each other in the direction from the main surface to the back surface of the semiconductor substrate SUB. A PN junction is formed at the interface between the n-type cathode region and the p-type anode region, and a depletion layer is formed near the PN junction. The interface between the n-type cathode region and the p-type anode region is the interface between the n-type semiconductor layer EP and the p-type substrate body SB.

When light enters the semiconductor device, the light that has passed through the dielectric film IL2, the dielectric film IL1, the dielectric film SBL, the shield electrode SE, the STI region 3b, and the oxide film 5 enters the n-type well region NW. Furthermore, the light enters the aforementioned depletion layer by passing through the n-type well region NW and the n-type semiconductor layer EP under the n-type well region NW. As a result, a large number of electron-hole pairs are generated in the depletion layer. The electrons generated in the depletion layer flow to the n-type semiconductor region NC via the n-type semiconductor layer EP and the n-type well region NW, and further flow to the cathode wiring M1C via the metal silicide layer SL and a plug PG1C on the n-type semiconductor region NC. On the other hand, the holes generated in the depletion layer flow to the p-type semiconductor region PC via the p-type substrate body SB, the p-type buried layer PBL, the p-type semiconductor region PS, and the p-type well region PW1, and further flow to the anode wiring M1A via the metal silicide layer SL and a plug PG1A on the p-type semiconductor region PC. As a result, current flows from the cathode wiring M1C via the photodiode to the anode wiring M1A.

The n-type impurity concentration of the n-type semiconductor region NC is higher than the n-type impurity concentration of the n-type well region NW, and the plug PG1C is connected to the n-type semiconductor region NC, and the cathode wiring M1C is connected to the plug PG1C. Therefore, the n-type semiconductor region NC is an electron extraction part for extracting electrons generated in the photodiode from the semiconductor substrate SUB to the plug PG1C. The plug PG1C is located on the metal silicide layer SL on the n-type semiconductor region NC. The plug PG1C is electrically connected to the n-type semiconductor region NC via the metal silicide layer SL on the n-type semiconductor region NC, and is electrically connected to the n-type cathode region via the n-type semiconductor region NC. The n-type semiconductor region NC is a contact part for connecting the plug PG1C to the semiconductor substrate SUB.

In plan view, the n-type semiconductor region NC is included in the n-type well region NW. In FIGS. 17 and 18, in plan view, the n-type semiconductor region NC is formed along the periphery of the n-type well region NW. In plan view, the shield electrode SE does not overlap the n-type semiconductor region NC.

In plan view, the p-type semiconductor region PC, the p-type well region PW1, the p-type semiconductor region PS, and the p-type buried layer PBL overlap each other. The p-type well region PW1 exists under the p-type semiconductor region PC, the p-type semiconductor region PS exists under the p-type well region PW1, the p-type buried layer PBL exists under the p-type semiconductor region PS, and the p-type substrate body SB exists under the p-type buried layer PBL. The p-type semiconductor region PE is formed by the p-type semiconductor region PC, the p-type well region PW1, the p-type semiconductor region PS, and the p-type buried layer PBL. The p-type semiconductor region PE is disposed on the p-type substrate body SB as a p-type anode region, and reaches the p-type substrate body SB from the main surface of the semiconductor substrate SUB. The p-type semiconductor region PE electrically connects the plug PG1A and the p-type semiconductor substrate. The p-type semiconductor region PE is formed so as to surround the n-type cathode region configured by the n-type well region NW and the n-type semiconductor layer EP in plan view.

The n-type impurity concentration of the p-type semiconductor region PC is higher than the n-type impurity concentration of the p-type well region PW, and the plug PG1A is connected to the p-type semiconductor region PC, and the anode wiring M1A is connected to the plug PG1A. Therefore, the p-type semiconductor region PC is a hole extraction part for extracting holes generated in the photodiode from the semiconductor substrate SUB to the plug PG1A. The plug PG1A is disposed on the metal silicide layer SL on the p-type semiconductor region PC. The plug PG1A is electrically connected to the p-type semiconductor region PC via the metal silicide layer SL on the p-type semiconductor region PC, and further electrically connected to the p-type substrate body SB via the p-type semiconductor region PC, the p-type well region PW1, the p-type semiconductor region PS, and the p-type buried layer PBL. The p-type semiconductor region PC is a contact part for connecting the plug PG1A to the semiconductor substrate SUB.

At the main surface of the semiconductor substrate SUB, the plurality of STI regions 3b are formed on the n-type well region NW. That is, in plan view, the plurality of STI regions 3b are disposed in the n-type well region NW. In plan view, it is preferable that the plurality of STI regions 3b are disposed in an array. In FIGS. 17 and 18, the planar shape of each of the plurality of STI region 3b is rectangular or square. Also, in FIGS. 17 and 18, thirty-six STI regions 3b are disposed in an array, but the number of STI regions 3b is not limited to thirty-six.

At the main surface of the semiconductor substrate SUB, the oxide film 5 is formed between the plurality of STI regions 3b. That is, the oxide film 5 is formed on the surface of the n-type well region NW between adjacent STI regions 3b. The plurality of STI regions 3b and the oxide film 5 are formed at the main surface of the semiconductor substrate SUB in the photodiode forming region 1A. In plan view, the plurality of STI regions 3b and the oxide film 5 are included in the n-type well region NW.

The shield electrode SE for noise shielding is formed on the plurality of STI regions 3b and the oxide film 5. The shield electrode SE does not contact the semiconductor layer EP, and the plurality of STI regions 3b and the oxide film 5 are interposed between the shield electrode SE and the semiconductor layer EP. In plan view, the shield electrode SE is included in the n-type well region NW. In plan view, although most of the n-type well region NW overlaps the shield electrode SE, the n-type semiconductor region NC does not overlap the shield electrode SE. Also, in plan view, each STI region 3b overlaps the shield electrode SE.

The shield electrode SE has a light-transmitting property that allows light entering the semiconductor device to pass through. The shield electrode SE is, for example, made of a polycrystalline silicon film. The shield electrode SE has a function to electromagnetically shield the photodiode. The presence of the shield electrode SE stabilizes the surface potential of the n-type cathode region of the photodiode. As a result, the resistance of the photodiode to noise can be increased.

Furthermore, by interposing the plurality of STI regions 3b and the oxide film 5 between the shield electrode SE and the n-type well region NW, the cathode region of the photodiode and the shield electrode SE can be electrically isolated, and the parasitic capacitance between the cathode region of the photodiode and the shield electrode SE can be reduced.

The shield electrode SE is connected to the plug PG1L. The plug PG1L is disposed on the metal silicide layer SL on the shield electrode SE. The plug PG1L is electrically connected to the shield electrode SE via the metal silicide layer SL.

The shield electrode SE and the p-type semiconductor region PC are electrically connected via the metal silicide layer SL and the plugs PG1A, PG1L, PG2 and the wirings M1A, M1L, M2A. Therefore, the same potential (preferably ground potential) is supplied to the shield electrode SE and the p-type semiconductor region PC. A higher potential (preferably positive potential) than the potential of the p-type semiconductor region PC is supplied to the n-type semiconductor region NC via the plug PG1C from the cathode wiring M1C. As a result, the n-type cathode region of the photodiode becomes a higher potential than the p-type anode region, and when light enters the photodiode, a current flows as described above.

At the boundary between the n-type cathode region configured by the n-type well region NW and the n-type semiconductor layer EP, and the p-type semiconductor region PE configured by the p-type semiconductor region PC, the p-type well region PW1, the p-type semiconductor region PS, and the p-type buried layer PBL, the STI region 3a is disposed. In another view, in plan view, the STI region 3a is disposed between the n-type semiconductor region NC and the p-type semiconductor region PC. In yet another view, in plan view, the STI region 3a is disposed between the plug PG1C and the plug PG1A. This STI region 3a electrically isolates the n-type cathode region and the p-type semiconductor region PE. In plan view, the STI region 3a surrounds the n-type cathode region.

As explained in relation to the manufacturing step of the semiconductor device, the thickness of the STI region 3b is smaller than the thickness of the STI region 3a. In another view, the height position of the upper surface of the STI region 3b is lower than the height position of the upper surface of the STI region 3a. The height positions of the bottom surfaces of the STI region 3a and the STI region 3b are the same.

### Background of Study

A semiconductor device including a photodiode has a semiconductor substrate, an anode region and a cathode region formed on the semiconductor substrate, a dielectric layer formed on the cathode region, and a noise shield with light-transmitting property formed on the dielectric layer. The dielectric layer on the cathode region is formed to reduce the parasitic capacitance between the shield electrode and the cathode region. Light that has passed through the shield electrode and the dielectric layer under the shield electrode enters the cathode region.

The present inventors consider using an STI region formed by the STI method as the dielectric layer for electrically isolating the cathode region of the photodiode and the shield electrode. For example, when forming a photodiode and a transistor element together on the semiconductor substrate, it is desirable to use an STI region as an element isolation region for the transistor element. Accordingly, if an STI region is used as a dielectric film for electrically isolating the cathode region of the photodiode and the shield electrode, the number of manufacturing steps can be reduced.

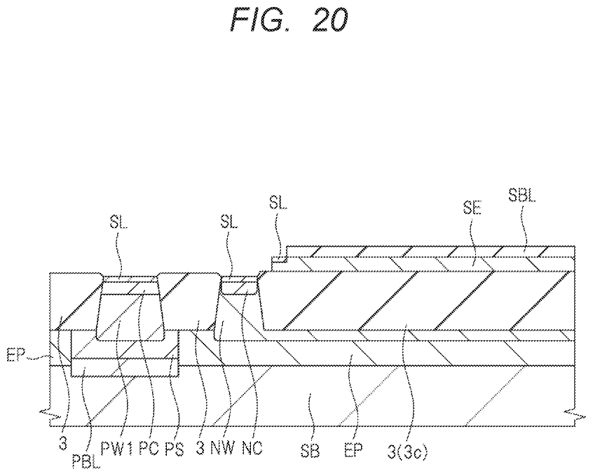

FIG. 20 is a main portion cross-sectional view of a semiconductor device in the first examined example studied by the present inventor. FIG. 20 shows a cross-section corresponding to the above-described FIG. 19. However, in FIG. 20, the dielectric films IL1, IL2, the plugs PG1, PG2, and the wirings M1, M2 shown in the above-described FIG. 19 are omitted from the illustration.

In the case of the first examined example shown in FIG. 20, one STI region 3c is formed on the n-type well region NW, and the shield electrode SE is formed on the STI region 3c. The area of the STI region 3c is larger than an area of each STI region 3d in the second examined example described later. In the case of the first examined example, a step corresponding to the etching step in the above-described FIG. 6 is not performed, and what corresponds to the above-described oxide film 5 is not formed.

In the case of the first examined example shown in FIG. 20, by interposing the STI region 3c between the shield electrode SE and the n-type well region NW, it is possible to electrically isolate the cathode region of the photodiode and the shield electrode SE, and to reduce the parasitic capacitance between the cathode region of the photodiode and the shield electrode SE.

However, according to the study by the present inventor, it was found that the following problems occur in the case of the first examined example.

That is, since the area of the STI region 3c in the first examined example is larger than the area of each STI region 3d in the second examined example described later, dishing is likely to occur in the CMP step for forming the STI region 3c. When dishing occurs, the thickness of the central part of the STI region 3c becomes smaller than the thickness of the peripheral part of the STI region 3c. This may lead to a decrease in the performance of the semiconductor device including a photodiode. Therefore, it is undesirable for dishing to occur in the STI region 3c.

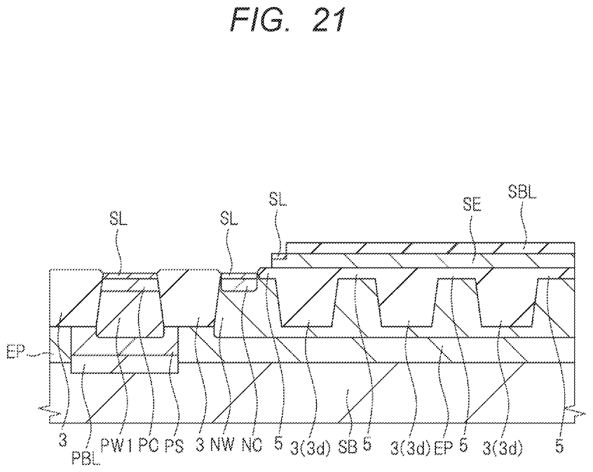

FIG. 21 is a main portion cross-sectional view of a semiconductor device in the second examined example studied by the present inventor. FIG. 21 shows a cross-section corresponding to the above-described FIGS. 19 and 20. In FIG. 21 as well, the dielectric films IL1, IL2, the plugs PG1, PG2, and the wirings M1, M2 shown in the above-described FIG. 19 are omitted from the illustration.

In the case of the second examined example shown in FIG. 21, the plurality of STI regions 3d are interposed between the shield electrode SE and the n-type well region NW. The oxide film 5 is formed between the plurality of STI regions 3d. However, in the case of the second examined example, a step corresponding to the etching step in the above-described FIG. 6 is not performed. Therefore, in the case of the second examined example shown in FIG. 21, each of the STI regions 3 has the same thickness.

In the case of the second examined example shown in FIG. 21, by interposing the plurality of STI regions 3d and the oxide film 5 between the shield electrode SE and the n-type well region NW, it is possible to electrically isolate the cathode region of the photodiode and the shield electrode SE, and to reduce the parasitic capacitance between the cathode region of the photodiode and the shield electrode SE.

In the case of the second examined example, the plurality of STI regions 3d are interposed between the shield electrode SE and the n-type well region NW. Therefore, compared to the planar dimensions (area) of the STI region 3c in the first examined example, it is possible to reduce the planar dimensions (area) of each STI region 3d in the second examined example. As a result, in the case of the second examined example, it is possible to suppress or prevent dishing from occurring when forming the STI region 3d.

However, according to the study by the present inventor, in the case of the second examined example, it was found that there is a possibility that crystal defects may occur in the semiconductor substrate SUB under the STI region 3d due to the stress caused by the STI region 3d. The causes of the occurrence of crystal defects will be described below.

The first cause is that the volume of the STI region 3d is large. If the volume of the STI region 3d is large, the stress caused by the STI region 3d tends to be large.

The second cause is that after forming the STI region 3d, the oxide film 5 is formed by thermal oxidation. In the thermal oxidation step for forming the oxide film 5, the stress attributable to the STI region 3d tends to increase due to the expansion of the STI region 3d.

The third cause is that after forming the oxide film 5 by thermal oxidation, a high-temperature heat treatment (specifically, a heat treatment of 1000 degrees Celsius or more) is applied to the semiconductor substrate SUB. In the state where the stress attributable to the STI region 3d has increased due to the first and second causes, when the high-temperature heat treatment step (specifically, a heat treatment of 1000 degrees Celsius or more) is performed, crystal defects are likely to occur in the semiconductor substrate SUB under the STI region 3d.

Therefore, due to the first, second, and third causes, crystal defects are likely to occur in the semiconductor substrate SUB under the STI region 3d. The occurrence of crystal defects in the semiconductor substrate SUB under the STI region 3d means that crystal defects occur in the cathode region or anode region of the photodiode, leading to a decrease in the performance of the semiconductor device including the photodiode. Therefore, in order to improve the performance of the semiconductor device including the photodiode, the semiconductor device needs to prevent the stress caused by the STI region 3d from causing crystal defects in the semiconductor substrate SUB under the STI region 3d.

### Main Features and Effects

The semiconductor device of the present embodiment includes a photodiode and has the semiconductor substrate SUB, the p-type anode region (p-type substrate body SB) formed in the semiconductor substrate SUB, and the n-type cathode region (n-type well region NW and n-type semiconductor layer EP) formed on the p-type anode region in the semiconductor substrate SUB. the plurality of STI regions 3b are formed on the n-type cathode region and at the main surface of the semiconductor substrate SUB, and the oxide film 5 is formed between the plurality of STI regions 3b and at the main surface of the semiconductor substrate SUB.

Compared to the planar dimensions of the STI region 3c in the first examined example, it is possible to reduce the planar dimensions of each STI region 3b in the present embodiment. Therefore, even in the present embodiment, it is possible to suppress or prevent dishing from occurring when forming the STI region 3b in the photodiode formation region 1A.

One of the main features of the present embodiment is that the manufacturing step of the semiconductor device includes the etching step shown in FIG. 6, and in this etching step, the plurality of STI regions 3b are etched.

In the present embodiment, by etching the plurality of STI regions 3b in the etching step shown in FIG. 6, it is possible to reduce the thickness of each STI region 3b, and therefore, it is possible to reduce the volume of each STI region 3b. That is, the thickness of each STI region 3b in the present embodiment can be made smaller than the thickness of each STI region 3d in the second examined example. Therefore, the volume of each STI region 3b in the present embodiment can be made smaller than the volume of each STI region 3d in the second examined example.

The larger the volume of each STI region 3, the more likely the stress caused by the STI region 3 is to increase. In the present embodiment, as a result of reducing the volume of each STI region 3b by etching the plurality of STI regions 3b in the etching step shown in FIG. 6, it is possible to suppress the stress caused by the STI region 3b.

Also, in the present embodiment, the step of etching the STI region 3b (the etching step shown in FIG. 6) is performed before the step of forming the oxide film 5 (the thermal oxidation step shown in FIG. 7). After the volume of each STI region 3b is reduced, thermal oxidation for forming the oxide film 5 is performed. In other words, thermal oxidation for forming the oxide film 5 is performed in a state where the volume of each STI region 3b is reduced. As a result, even if the STI region 3b expands during the thermal oxidation for forming the oxide film 5, the stress caused by the expansion of the STI region 3b can be suppressed because the volume of the STI region 3b is reduced.

Also, in the present embodiment, after performing the step of forming the STI region 3, the step of etching the STI region 3b, and the step of forming the oxide film 5, a step of performing a high-temperature heat treatment (specifically, a heat treatment of 1000 degrees Celsius or higher) on the semiconductor substrate SUB is included. Such a high-temperature heat treatment is, for example, the heat treatment step shown in FIG. 9. The heat treatment step shown in FIG. 9 is a heat treatment step after ion implantation to form the n-type drift region DF. Depending on the type of transistor element to be formed in the transistor formation region 1B, other high-temperature (1000 degrees Celsius or higher) heat treatment steps may also be performed. If a high-temperature heat treatment step (specifically, a heat treatment of 1000 degrees Celsius or higher) is performed in a state where the stress caused by the STI region 3b is large, crystal defects are likely to occur in the semiconductor substrate SUB under the STI region 3b.

In contrast, in the present embodiment, the volume of each STI region 3b is reduced by the etching step shown in FIG. 6, which can suppress the stress caused by the STI region 3b. Therefore, it is possible to suppress or prevent the occurrence of crystal defects in the semiconductor substrate SUB under the STI region 3b.

Thus, in the present embodiment, by performing an etching step (the etching step shown in FIG. 6) on the STI region 3b after the step of forming the STI region 3, the stress caused by the STI region 3b can be suppressed. As a result, it is possible to suppress or prevent the occurrence of crystal defects in the semiconductor substrate SUB under the STI region 3b. As a result, the performance of the semiconductor device including the photodiode can be improved.

Another main feature of the present embodiment is that in the etching step shown in FIG. 6, the STI region 3b is etched, but the STI region 3a is not etched.

In the present embodiment, after the etching step shown in FIG. 6, the thickness of the STI region 3b becomes smaller than the thickness of the STI region 3a, and the height position of the upper surface of the STI region 3b becomes lower than the height position of the upper surface of the STI region 3a.

Specifically, at the main surface of the semiconductor substrate SUB, the STI region 3b is applied to the plurality of STI regions 3 formed on the n-type cathode region. In other words, in plan view, the STI region 3b is applied to the plurality of STI regions 3 located in the n-type cathode region. This can suppress or prevent the occurrence of crystal defects in the n-type cathode region due to the stress caused by the STI region 3. Therefore, the performance of the semiconductor device including the photodiode can be improved.

On the other hand, at the main surface of the semiconductor substrate SUB, the STI region 3a is disposed between the n-type cathode region and the p-type semiconductor region PE. That is, at the main surface of the semiconductor substrate SUB, the STI region 3a is disposed between the n-type semiconductor region NC and the p-type semiconductor region PC.

As shown in FIG. 19, the STI region 3a disposed between the n-type semiconductor region NC and the p-type semiconductor region PC has a function of electrically isolating the p-type region formed of the p-type semiconductor region PC and the p-type well region PW1 and the n-type region formed of the n-type semiconductor region NC and the n-type well region NW. However, if charge is unintentionally stored in this STI region 3a, an n-type inversion layer is formed along the sidewall of the STI region 3a adjacent to the p-type well region PW1, and there is a risk that a leak current will flow in the n-type inversion layer. That is, there is a concern that a leak current will flow between the metal silicide layer SL on the p-type semiconductor region PC and the n-type well region NW along the sidewall and bottom surface of the STI region 3a disposed between the n-type semiconductor region NC and the p-type semiconductor region PC. This leak current degrades the performance of the semiconductor device including the photodiode, so it is desirable to suppress or prevent it.

In contrast, in the present embodiment, since the STI region 3a, which is thicker than the STI region 3b, is disposed between the n-type semiconductor region NC and the p-type semiconductor region PC, the above-mentioned leak current can be suppressed or prevented. As a result, the performance of the semiconductor device including the photodiode can be improved.

Also, as shown in FIGS. 1 to 16, when forming the photodiode and the transistor element on the semiconductor substrate SUB, it is desirable to apply the STI region 3a to the STI region 3 defining the active region where the transistor element is formed. The STI region 3 defining the active region surrounds the active region in plan view.

The STI region 3, which defines the active region where the transistor element is formed, has the function of electrically isolating that active region from other active regions. The thinner the STI region 3, the harder it is to achieve electrical isolation by the STI region 3. Therefore, the thickness of the STI region 3, which defines the active region where the transistor element is formed, needs to be set to an appropriate thickness as an element isolation region. However, as mentioned above, in order to prevent the occurrence of crystal defects in the n-type anode region of the photodiode due to the STI region 3, it is desirable to reduce the thickness of the STI region 3 located on the n-type anode region of the photodiode.

Therefore, in the present embodiment, at the stage of forming the STI region 3 as shown in the above FIG. 3, the thickness of the STI region 3a, which defines the active region where the transistor element is formed, is set to a thickness that can sufficiently achieve electrical isolation. Then, the etching step of FIG. 6 is performed, the STI region 3b is etched, and the STI region 3a is not etched. This allows the thickness of the STI region 3a, which defines the active region where the transistor element is formed, to be maintained while reducing the thickness of the STI region 3b located on the n-type anode region of the photodiode. As a result, the performance of the semiconductor device including the photodiode and the transistor element can be improved.

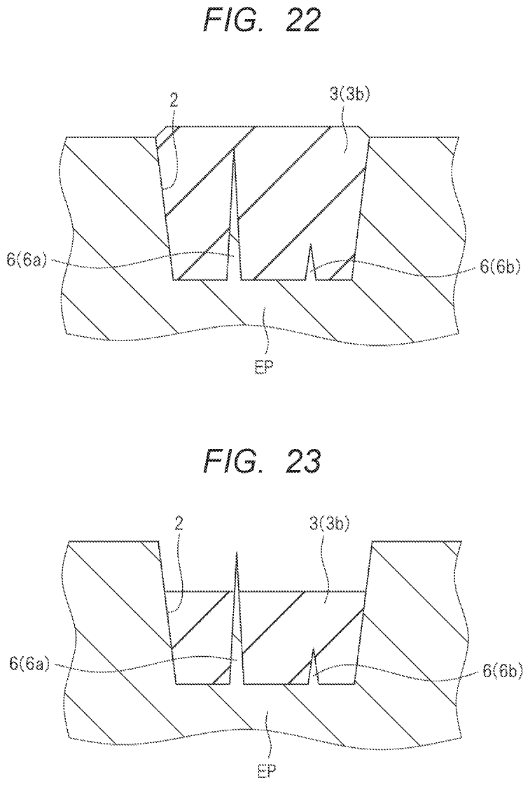

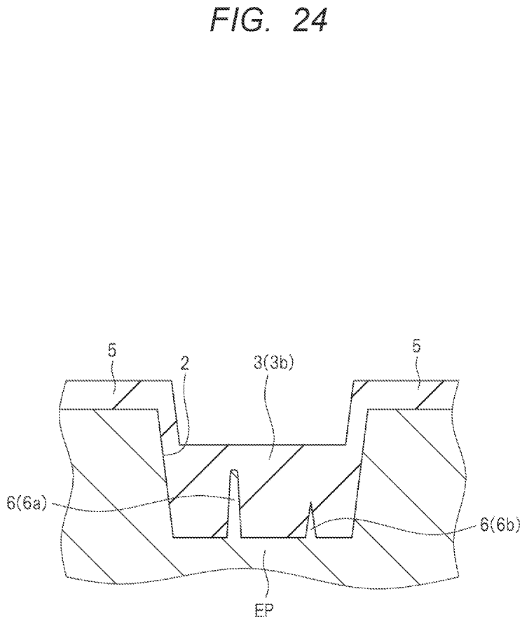

Next, the effect of the step of forming the oxide film 5 (thermal oxidation step of FIG. 7) will be explained with reference to the explanatory diagrams of FIGS. 22 to 24. FIGS. 22 to 24 show a partially enlarged cross-sectional view of a part of the photodiode formation region 1A. FIG. 22 corresponds to the same step stage as the above FIG. 3, FIG. 23 corresponds to the same step as the above FIG. 6, and FIG. 24 corresponds to the same step as the above FIG. 7.

FIG. 22 shows a case where a needle-like protrusion 6 is generated on the bottom surface of the trench 2 when the trench 2 is formed on the semiconductor substrate SUB. This protrusion 6 may occur when, for example, a foreign substance that inhibits etching adheres to the main surface of the semiconductor substrate SUB when the trench 2 is formed by etching. When the STI region 3 is formed in a state where the protrusion 6 is generated at the bottom of the trench 2, the protrusion 6 is covered with the STI region 3 as shown in FIG. 22.

When the etching step of the above FIG. 6 is performed to etch the STI region 3b, the thickness of the STI region 3b becomes smaller as shown in FIG. 23. If the protrusion 6 was generated on the bottom surface of the trench 2, when the thickness of the STI region 3b is reduced by etching, a part of the protrusion 6 may protrude from the upper surface of the STI region 3b. In FIG. 23, a protrusion 6a and a protrusion 6b are shown, the height of the protrusion 6a is greater than the height of the protrusion 6b, a part of the protrusion 6a protrudes from the upper surface of the STI region 3b, and the protrusion 6b does not protrude from the upper surface of the STI region 3b.

Then, by performing the thermal oxidation step of the above FIG. 7, the oxide film 5 is formed as shown in FIG. 24. At this time, the protrusion 6a protruding from the upper surface of the STI region 3b can also be oxidized. This is because the protrusion 6a is made of the same material as the semiconductor layer EP. As a result, as shown in FIG. 24, the height of the protrusion 6a is reduced, and the entire protrusion 6a is covered with the STI region 3b. Also, the entire protrusion 6b is covered with the STI region 3b. After that, the steps explained with reference to FIGS. 8 to 16 are performed.

The shield electrode SE is formed on the STI region 3b. If the protrusion 6 is generated on the bottom surface of the trench 2, when the protrusion 6 and the shield electrode SE come into contact, the n-type cathode region of the photodiode and the shield electrode SE are electrically connected. This needs to be prevented because it results in the n-type cathode region and the p-type anode region being electrically connected via the shield electrode SE and the wirings M1L, M1A, M2A.

In the present embodiment, even when the protrusion 6 is generated on the bottom surface of the trench 2, it is possible to oxidize the protrusion 6a protruding from the upper surface of the STI region 3b during thermal oxidation for forming the oxide film 5. As a result, as shown in FIG. 24, since all the protrusions 6 are covered with the STI region 3b, it is possible to prevent the protrusion 6 and the shield electrode SE from coming into contact. Therefore, it is possible to improve the reliability of the semiconductor device including the photodiode.

By performing the oxide film 5 forming step, even when the protrusion 6 is generated on the bottom surface of the trench 2, it is possible to prevent the protrusion 6 and the shield electrode SE from coming into contact.

The invention made by the present inventor has been described above in detail based on the embodiment, but the present invention is not limited to the embodiment described above, and it is needless to say that various modifications can be made without departing from the gist thereof.

What is claimed is:

1. A method of manufacturing a semiconductor device including a photodiode, the method comprising:
(a) preparing a semiconductor substrate;
(b) forming a plurality of first STI regions at a main surface of the semiconductor substrate;
(c) after the (b), etching the plurality of first STI regions;
(d) after the (c), forming an oxide film between the plurality of first STI regions by a thermal oxidation treatment at the main surface of the semiconductor substrate; and
(e) after the (d), performing a heat treatment of 1000 degrees Celsius or more on the semiconductor substrate,
wherein the plurality of first STI regions are located in a cathode region of a first conductivity type of the photodiode in plan view.

2. The method according to claim 1,
wherein in the (c), thicknesses of the plurality of first STI regions are reduced by etching the plurality of first STI regions.

3. The method according to claim 1, comprising:
(f) forming an electrode on the plurality of first STI regions and the oxide film.

4. The method according to claim 1,
wherein in the (b), a second STI region is formed at the main surface of the semiconductor substrate,
wherein the method comprising:
(b1) after the (b) and before the (c), forming a first dielectric film on the main surface of the semiconductor substrate, the first dielectric film covering the second STI region and exposing the plurality of the first STI regions,
wherein in the (c), the second STI region is covered with the first dielectric film, and the plurality of first STI regions exposed from the first dielectric film are etched.

5. The method according to claim 4, comprising:
(d1) after the (d), removing the first dielectric film.

6. The method according to claim 4,
wherein after the (c), a thickness of each of the plurality of first STI regions is smaller than a thickness of the second STI region.

7. The method according to claim 4,
wherein the second STI region defines an active region in the semiconductor substrate where a transistor element is formed.

8. The method according to claim 7, comprising:
(g) forming an LDMOSFET in the active region in the semiconductor substrate,
wherein the heat treatment in the (e) is performed to form a semiconductor region of the LDMOSFET.

9. The method according to claim 8,
wherein in the (d), a field oxide film is formed at a part of a surface of the active region by the heat treatment.

10. The method according to claim 4,
wherein the semiconductor substrate includes an anode region of a second conductivity type opposite the first conductivity type of the photodiode,
wherein the method comprising:
(h) forming a first semiconductor region of the second conductivity type in the semiconductor substrate, the first semiconductor region reaching the anode region from the main surface of the semiconductor substrate,
wherein at the main surface of the semiconductor substrate, the second STI region is disposed between the cathode region and the first semiconductor region.

11. The method according to claim 10, comprising:
(i) forming a first plug on the cathode region in the semiconductor substrate and forming a second plug on the first semiconductor region in the semiconductor substrate, the first plug being electrically connected to the cathode region, the second plug being electrically connected to the first semiconductor region,
wherein the second plug is electrically connected to the anode region via the first semiconductor region.

12. The method according to claim 1,
wherein the plurality of first STI regions are disposed in an array in plan view.

13. A semiconductor device comprising:
a semiconductor substrate;
an anode region of a first conductivity type of a photodiode, the anode region being formed in the semiconductor substrate;
a cathode region of a second conductivity type opposite the first conductivity type of the photodiode, the cathode region being formed on the anode region and in the semiconductor substrate;
a plurality of first STI regions formed on the cathode region and at a main surface of the semiconductor substrate;
an oxide film formed between the plurality of first STI regions and at the main surface of the semiconductor substrate;
an electrode formed on the plurality of first STI regions and on the oxide film;
a first plug disposed on the cathode region and electrically connected to the cathode region;
a first semiconductor region of the first conductivity type formed on the anode region and in the semiconductor substrate;
a second plug disposed on the first semiconductor region and electrically connected to the first semiconductor region; and
a second STI region disposed between the cathode region and the first semiconductor region and at the main surface of the semiconductor substrate,
wherein the second plug is electrically connected to the anode region via the first semiconductor region, and
wherein a thickness of each of the plurality of first STI regions is smaller than a thickness of the second STI region.

14. The semiconductor device according to claim 13,
wherein a height position of an upper surface of each of the plurality of first STI regions is lower than a height position of an upper surface of the second STI region.

15. The semiconductor device according to claim 14,
wherein a bottom surface of each of the plurality of first STI regions is the same height as a bottom surface of the second STI region.

16. The semiconductor device according to claim 13,
wherein the plurality of first STI regions are disposed in an array in plan view.

17. The semiconductor device according to claim 13, comprising:
a third plug disposed on the electrode and electrically connected to the electrode; and
a wiring electrically connecting the second plug and the third plug.

18. The semiconductor device according to claim 13, comprising:
a third STI region formed at the main surface of the semiconductor substrate and defining an active region; and
a transistor element formed in the active region,
wherein the thickness of each of the plurality of first STI regions is smaller than a thickness of the third STI region.

19. The semiconductor device according to claim 18,
wherein a height position of an upper surface of each of the plurality of first STI regions is lower than a height position of an upper surface of the second STI region and lower than a height position of an upper surface of the third STI region.
